(19) United States
(12) Patent Application Publication
(10) Pub. No.: US 2016/0197594 A1
(43) Pub. Date: Jul. 7, 2016

(54) RESONATOR DEVICE, ELECTRONIC APPARATUS AND MOVING OBJECT

(71) Applicant: Seiko Epson Corporation, Tokyo (JP)

(72) Inventors: Masanori HANZAWA, Minowa (JP); Toshiaki SATO, Minowa (JP); Masayuki KIKUSHIMA, Ina (JP)

(21) Appl. No.: 14/988,052

(22) Filed: Jan. 5, 2016

(30) Foreign Application Priority Data
Jan. 6, 2015 (JP) 2015-000673

(51) Int. Cl. H03H 9/05; H01C 7/00; H03H 9/10

(52) U.S. Cl. CPC H03H 9/0552; H03H 9/10; H01C 7/008

(57) ABSTRACT

A quartz crystal resonator includes a quartz crystal resonator element, a thermistor, and a package base having a first main surface and a second main surface which are respectively a front surface and a back surface. The quartz crystal resonator element is mounted on the first mounting surface on the first main surface side of the package base. The thermistor is mounted on the second mounting surface on the second main surface side of the package base. The package base has an overlapping section in which at least a portion of the first mounting surface overlaps at least a portion of the second mounting surface in a planar view. A thickness of the overlapping section is equal to or greater than 0.04 mm and less than 0.10 mm.

### BACKGROUND

1. Technical Field

The present invention relates to a resonator device, an electronic apparatus and a moving object which include the resonator device.

2. Related Art

In the related art, a piezoelectric device, which includes a piezoelectric resonator device, a temperature sensing component, and a container having a first containing section containing the piezoelectric resonator device, and a second containing section containing the temperature sensing component, is known as an example of a resonator device (for example, JP-A-2013-102315). The container includes a first insulating substrate having a penetration hole configuring the second containing section and a plurality of mounting terminals on a bottom section; a second insulating substrate which is stacked on and fixed to the first insulating substrate, has a first electrode pad for mounting the piezoelectric resonator device on a surface, and has a second electrode pad for mounting the temperature sensing component on a back surface; and a third substrate which is stacked on and fixed to a surface of the second substrate, and configures the first containing section.

In the piezoelectric device, at least one mounting terminal and the first electrode pad are electrically coupled to each other by a first thermal conduction section and a first wiring pattern, and at least another mounting terminal and the second electrode pad are electrically coupled to each other by a second thermal conduction section and a second wiring pattern. Thus, it is possible to reduce a temperature difference between temperature of the piezoelectric resonator device and temperature which is sensed by the temperature sensing component, and to obtain better frequency temperature characteristics.

In recent years, a resonator device represented by the piezoelectric device or the like which is used for an electronic apparatus, particularly a wireless communication apparatus such as a cellular phone having a GPS function is required to be more accurate.

Due to this, the piezoelectric device needs to be improved to obtain excellent frequency temperature characteristics and to further reduce a temperature difference between temperature of a piezoelectric resonator device and temperature which is sensed by a temperature sensing component.

### SUMMARY

An advantage of some aspects of the invention is to solve at least a part of the problems described above, and the invention can be implemented as the following forms or application examples.

### APPLICATION EXAMPLE 1

A resonator device according to this application example includes a resonator element; an electronic device; and a substrate including a first main surface and a second main surface which are respectively a front surface and a back surface, in which the resonator element is mounted on a first mounting surface on the first main surface side of the substrate, in which the electronic device is mounted on a second mounting surface on the second main surface side of the substrate, in which the substrate has an overlapping section in which at least a portion of the first mounting surface overlaps at least a portion of the second mounting surface in planar view, and in which a thickness of the overlapping section is equal to or greater than 0.04 mm and less than 0.10 mm.

According to this configuration, the resonator device includes the overlapping section in which at least a portion of the first mounting surface overlaps at least a portion of the second mounting surface. The resonator element and the electronic device in the substrate are mounted on the first mounting surface and the second mounting surface. Since the thickness of the overlapping section is equal to or greater than 0.04 mm and less than 0.10 mm, thermal conduction between the resonator element and the electronic device through the substrate is promoted.

As a result, for example, if the electronic device is a temperature sensing device, the resonator device can reduce a temperature difference between temperature of the resonator element and temperature which is sensed by the temperature sensing device, and can obtain excellent frequency temperature characteristics.

Accordingly, a variation width of the frequency is decreased, and thus, the resonator device can be accurate.

### APPLICATION EXAMPLE 2

In the resonator device according to the application example, it is preferable that the thickness of the overlapping section is equal to or greater than 0.04 mm and equal to or less than 0.08 mm.

According to this configuration, since the thickness of the overlapping section is equal to or greater than 0.04 mm and equal to or less than 0.08 mm, the resonator device can further promote thermal conduction between the resonator element and the electronic device through the substrate.

### APPLICATION EXAMPLE 3

In the resonator device according to the application example, it is preferable that the thickness of the overlapping section is equal to or greater than 0.04 mm and equal to or less than 0.06 mm.

According to this configuration, since the thickness of the overlapping section is equal to or greater than 0.04 mm and equal to or less than 0.06 mm, the resonator device can further promote thermal conduction between the resonator element and the electronic device through the substrate.

### APPLICATION EXAMPLE 4

In the resonator device according to the application example, it is preferable that the substrate has a stacked structure in which a first layer with a thickness equal to or greater than 0.04 mm and less than 0.10 mm is provided on the first main surface side and a second layer with a thickness equal to or greater than that of the first layer is provided on the second main surface side, that the first mounting surface and the second mounting surface are respectively the front surface and the back surface of the first layer, that the second layer has an opening larger than the electronic device in a planar view, and that the electronic device is contained in the opening.

According to this configuration, in the resonator device, the substrate has a stacked structure in which a first layer with a thickness equal to or greater than 0.04 mm and less than 0.10 mm is provided on the first main surface side and a second layer with a thickness equal to or greater than that of the first layer is provided on the second main surface side, the first mounting surface and the second mounting surface are respectively the front surface and the back surface of the first layer, and the electronic device is contained in the opening of the second layer.

Accordingly, in the resonator device, since the first layer of the substrate is a flat plate shape, it is easy to manage the thickness to a value equal to or greater than 0.04 mm and less than 0.10 mm. In addition, as the second layer with a thickness equal to or greater than that of the first layer is stacked on the first layer, it is possible to ensure the strength of the substrate.

In addition, since the electronic device is contained in the opening of the second layer, the resonator device can be thinned over all while ensuring the strength of the substrate.

### APPLICATION EXAMPLE 5

In the resonator device according to the application example, it is preferable that the substrate is stacked on the first main surface side of the first layer, and further includes a third layer of frame shape surrounding the resonator element.

According to this configuration, since the substrate is stacked on the first layer and further includes the third layer of frame shape surrounding the resonator element, in the resonator device, the internal space (concave section) which contains the resonator element in the substrate is provided, and it is possible to further increase the strength of the substrate.

### APPLICATION EXAMPLE 6

In the resonator device according to the application example, it is preferable that at least the overlapping section of the substrate employs aluminum nitride or silicon carbide as main components.

According to this configuration, since at least overlapping section of the substrate employs aluminum nitride or silicon carbide as main components, the resonator device has a relatively high thermal conductivity as a kind of ceramic (also referred to as ceramics) materials.

As a result, since thermal conduction between the resonator element and the electronic device through the substrate is further promoted, for example, if the electronic device is the temperature sensing device, the resonator device can further reduce the temperature difference between the temperature of the resonator element and the temperature which is sensed by the temperature sensing device, and can obtain more excellent frequency temperature characteristics.

### APPLICATION EXAMPLE 7

In the resonator device according to the application example, it is preferable that the electronic device is a temperature sensing device.

According to this configuration, since the electronic device is the temperature sensing device, the resonator device can reduce the temperature difference between temperature of the resonator element and temperature which is sensed by the temperature sensing device, and can obtain excellent frequency temperature characteristics.

### APPLICATION EXAMPLE 8

In the resonator device according to the application example, it is preferable that the temperature sensing device is a thermistor or a semiconductor device for temperature measurement.

According to this configuration, since the temperature sensing device is the thermistor or the semiconductor device for temperature measurement, the resonator device can accurately sense the surrounding temperature using the characteristics of the thermistor and the semiconductor device for temperature measurement.

### APPLICATION EXAMPLE 9

An electronic apparatus according to this application example includes the resonator device described in any one of the application examples.

According to this configuration, since the electronic apparatus of the present configuration includes the resonator device described in any one of the application examples, it is possible to provide the electronic apparatus having the effects described in any one of the application examples and exerting excellent performance.

### APPLICATION EXAMPLE 10

A moving object according to this application example includes the resonator device described in any one of the application examples.

According to this configuration, since the moving object of the present configuration includes the resonator device described in any one of the application examples, it is possible to provide the moving object having the effects described in any one of the application examples and exerting excellent performance.

### BRIEF DESCRIPTION OF THE DRAWINGS

The invention will be described with reference to the accompanying drawings, wherein like numbers reference like devices.

FIGS. 1A to 1C are schematic views illustrating a schematic configuration of a quartz crystal resonator according to a first embodiment, FIG. 1A is a plan view viewed from a lid side, FIG. 1B is a sectional view taken along line A-A of FIG. 1A, and FIG. 1C is a plan view viewed from a bottom surface side.

FIG. 2 is a circuit diagram relating to driving of the quartz crystal resonator including a temperature sensing device serving as an electronic device which is contained in the quartz crystal resonator according to the first embodiment.

FIG. 3 is a graph illustrating a relationship between a thickness t of a package base and a temperature difference between a first mounting surface side and a second mounting surface side.

FIG. 4 is a diagram illustrating a relationship between the thickness t of the package base and a mechanical strength.

FIG. 5 is a graph illustrating a relationship between the thickness t of the package base and yield of frequency temperature characteristics of the quartz crystal resonator.

FIGS. 6A to 6C are schematic views illustrating a schematic configuration of a quartz crystal resonator according to a modification example of the first embodiment, FIG. 6A is a plan view viewed from a lid side, FIG. 6B is a sectional view taken along line A-A of FIG. 6A, and FIG. 6C is a plan view viewed from a bottom surface side.

FIGS. 7A to 7C are schematic views illustrating a schematic configuration of a quartz crystal resonator according to a second embodiment, FIG. 7A is a plan view viewed from a lid side, FIG. 7B is a sectional view taken along line A-A of FIG. 7A, and FIG. 7C is a plan view viewed from a bottom surface side.

FIG. 8 is a schematic perspective view illustrating a cellular phone serving as an electronic apparatus.

FIG. 9 is a schematic perspective view illustrating an automobile serving as a moving object.

### DESCRIPTION OF EXEMPLARY EMBODIMENTS

Hereinafter, embodiments in which the present invention is specified will be described with reference to the drawings.

### First Embodiment

First of all, a quartz crystal resonator which is an example of a resonator device will be described.

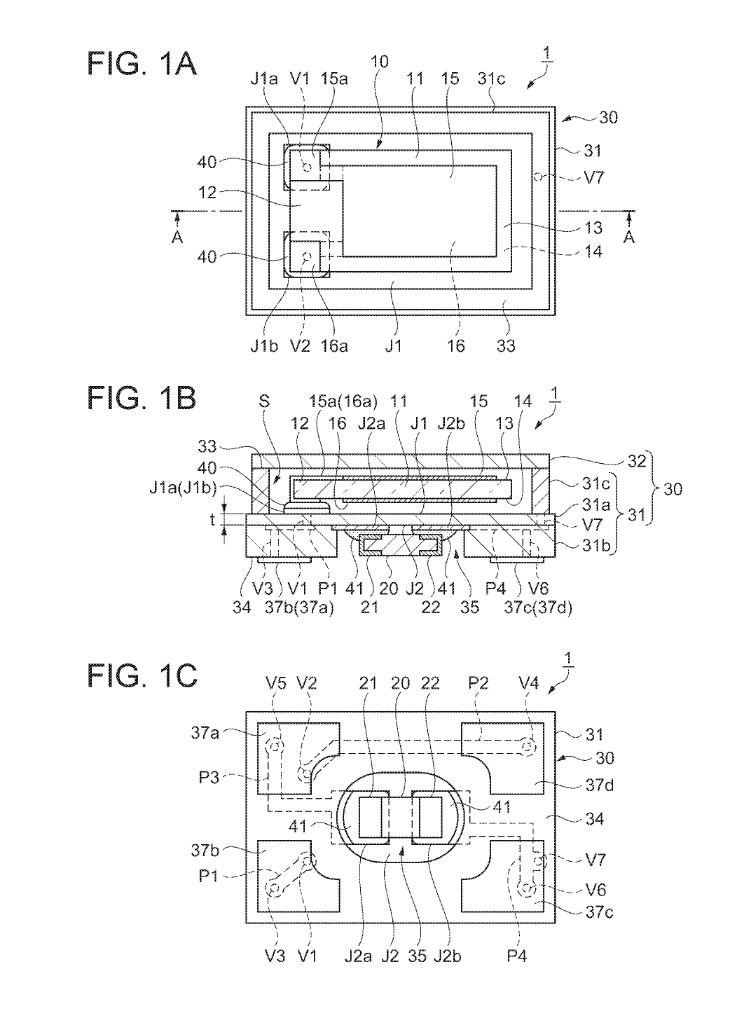

FIGS. 1A to 1C are schematic views illustrating a schematic configuration of a quartz crystal resonator according to a first embodiment, FIG. 1A is a plan view viewed from a lid side, FIG. 1B is a sectional view taken along line A-A of FIG. 1A, and FIG. 1C is a plan view viewed from a bottom surface side. A lid is omitted in the following plan views including FIG. 1A which are viewed from a lid side. In addition, for the sake of clarity, a size ratio of each configuration device is different from an actual size ratio.

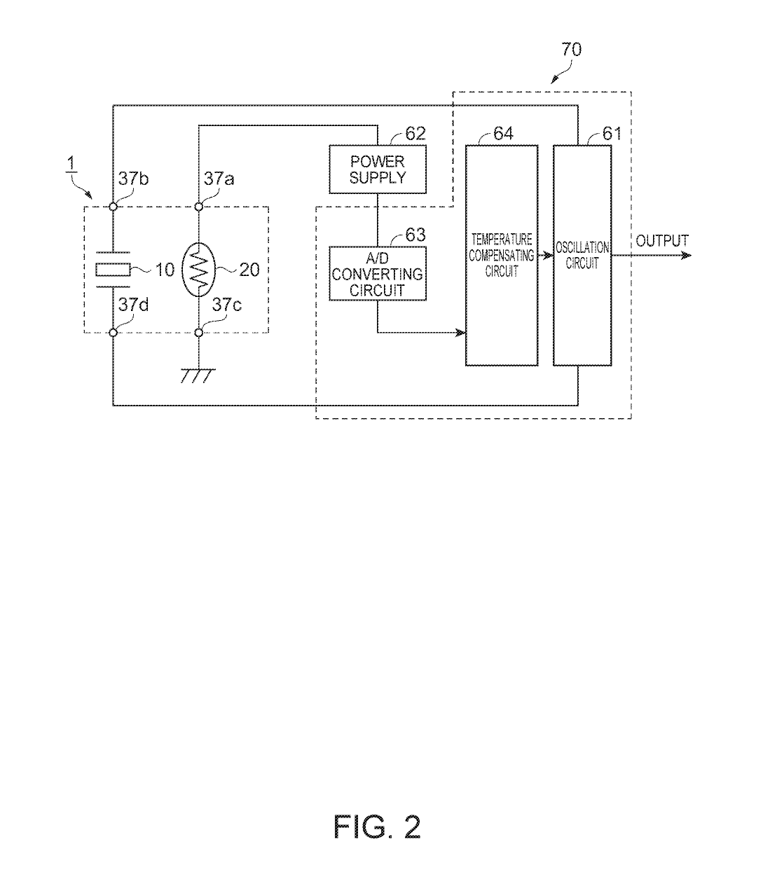

FIG. 2 is a circuit diagram relating to driving of the quartz crystal resonator including a temperature sensing device contained in the quartz crystal resonator according to the first embodiment.

As illustrated in FIG. 1A to 1C, a quartz crystal resonator 1 includes a quartz crystal resonator element 10 serving as a resonator element, a thermistor 20 which is an example of a temperature sensing device serving as an electronic device, and a package 30 in which the quartz crystal resonator element 10 and the thermistor 20 are contained.

The quartz crystal resonator element 10 is an AT-cut quartz crystal substrate which is obtained by cutting a rough quartz crystal or the like at a predetermined angle, in which a plane shape is formed in a substantially rectangular shape, and which has a vibration section 11 in which thickness shear vibration is excited and a base section 12 which is coupled to the vibration section 11, as one piece.

In the quartz crystal resonator element 10, lead-out electrodes 15a and 16a, which are led out from excitation electrodes 15 and 16 of a substantially rectangular shape that are formed on one main surface 13 of the vibration section 11 and on the other main surface 14 of the vibration section 11, are formed on the base section 12.

The lead-out electrode 15a is led out from the excitation electrode 15 of the one main surface 13 toward the base section 12 along a length direction (left-right direction of a sheet surface) of the quartz crystal resonator element 10, turns toward the other main surface 14 along aside surface of the base section 12, and extends to the other main surface 14 of the base section 12.

The lead-out electrode 16a is lead out from the excitation electrode 16 of the other main surface 14 toward the base section 12 along a length direction of the quartz crystal resonator element 10, turns toward the one main surface 13 along a side surface of the base section 12, and extends to the one main surface 13 of the base section 12.

For example, the excitation electrodes 15 and 16 and the lead-out electrodes 15a and 16a are formed of a metal-coated film having a configuration in which a base layer is formed of, for example, Cr (chrome), and Au (gold) or a metal that employs Au as main components is stacked on the base layer.

The thermistor 20 is, for example, a temperature sensing device (temperature sensing resistance device) of a chip type (rectangular shape), has electrodes 21 and 22 in both end sections thereof, and is a resistance body having a great change of electric resistance with respect to a temperature change.

For example, a thermistor, which is called a negative temperature coefficient (NTC) thermistor in which resistance decreases with respect to an increase of temperature, is used for the thermistor 20. Since a relationship between changes of temperature and a resistance value is linear, the NTC thermistor is frequently used as a temperature sensor.

The thermistor 20 is contained in the package 30, senses a temperature around the quartz crystal resonator element 10, and thereby performs a function of contributing to correction of a frequency variation according to temperature change of the quartz crystal resonator element 10 as a temperature sensor.

The package 30 has a substantially flat plate shape whose plane shape is substantially rectangular, includes a package base 31 which is a substrate having a first main surface 33 and a second main surface 34 that respectively form a front surface and a back surface, and a lid 32 of a flat shape which covers the first main surface 33 side of the package base 31, and is formed in a substantially rectangular shape.

The package base 31 has a stacked structure that includes a first layer 31a of a flat shape in which a surface of the first main surface 33 side becomes a first mounting surface J1 and a surface of the second main surface 34 side becomes a second mounting surface J2, a second layer 31b which has an opening in a central portion thereof, is stacked on the second mounting surface J2 of the first layer 31a, and has a side opposite to the stacked surface becoming the second main surface 34, and a third layer 31c of a frame shape which is stacked on the first mounting surface J1 of the first layer 31a and has a surface of the lid 32 side becoming the first main surface 33.

The first mounting surface J1 and the second mounting surface J2 of the first layer 31a respectively form a front surface and a back surface, the quartz crystal resonator element 10 is mounted in the first mounting surface J1, and the thermistor 20 is mounted in the second mounting surface J2.

A ceramic-based insulating material, such as, an aluminum oxide sintered body in which a ceramic green sheet is formed, stacked, and baked, a mullite sintered body, an aluminum nitride sintered body, a silicon carbide sintered body, or a glass ceramic sintered body, quartz crystal, glass, silicon (silicon with a high resistance), or the like is used for the first layer 31a and the second layer 31b of the package base 31.

An aluminum nitride sintered body or a silicon carbide sintered body, that uses aluminum nitride (thermal conductivity: approximately 150 to 280 W/(m·k)) or silicon carbide (thermal conductivity: approximately 100 to 350 W/(m·k)) as main components, and that has a relatively high thermal conductivity among the ceramic-based insulating materials, is used for the first layer 31a and the second layer 31b of the package base 31, and this is preferred from a viewpoint of promotion of thermal conduction of the package base 31.

The first layer 31a of the package base 31 is formed of a flat shape, and it is preferable that a thickness t thereof is equal to or greater than 0.04 mm and less than 0.10 mm. It is more preferable that the thickness t is equal to or greater than 0.04 mm and equal to or less than 0.08 mm. It is further more preferable that the thickness t is equal to or greater than 0.04 mm and equal to or less than 0.06 mm.

The second layer 31b is formed of a flat shape having an opening, and it is preferable that a thickness thereof is equal to or greater than that of the first layer 31a. It is more preferable that the thickness thereof is less than 0.30 mm. In addition, the opening of the second layer 31b is formed more largely than the thermistor 20 in a planar view.

The third layer 31c and the lid 32 use the same materials as the first layer 31a and the second layer 31b, or a metal such as kovar or 42 alloy. The third layer 31c has a frame shape surrounding the quartz crystal resonator element 10, and it is preferable that a thickness thereof is greater than that of the quartz crystal resonator element 10.

In other words, the package base 31 has an overlapping section (here, the first layer 31a) in which at least a portion of the first mounting surface J1 overlaps at least a portion of the second mounting surface J2 in a planar view, and it is preferable that a thickness of the overlapping section is equal to or greater than 0.04 mm and less than 0.10 mm. It is more preferable that the thickness of the overlapping section is equal to or greater than 0.04 mm and equal to or less than 0.08 mm. It is further more preferable that the thickness of the overlapping section is equal to or greater than 0.04 mm and equal to or less than 0.06 mm.

Internal terminals J1a and J1b are provided at a position facing the lead-out electrodes 15a and 16a of the quartz crystal resonator element 10, in the first mounting surface J1 of the package base 31.

In the quartz crystal resonator element 10, the lead-out electrodes 15a and 16a are bonded to the internal terminals J1a and J1b through a conductive adhesive 40 such as epoxy-base, silicone-base, or polyimide-base to which a conductive material such as a metal filler is mixed.

As a result, the quartz crystal resonator element 10 is mounted on the first mounting surface J1 of the first main surface 33 side of the package base 31 in a state of being surrounded by the third layer 31c of the package base 31.

In the quartz crystal resonator 1, in a state in which the quartz crystal resonator element 10 is bonded to the internal terminals J1a and J1b of the package base 31, the third layer 31c of the package base 31 is covered with the lid 32, the package base 31 and the lid 32 are bonded together by seam welding or by a bonding member such as, low-melting-point glass, or adhesive, and thereby an internal space S including the first layer 31a and, the third layer 31c of the package base 31, and the lid 32 is sealed in an airtight manner.

FIGS. 1A to 1C illustrate a state in which the third layer 31c formed by a metal and the lid 32 formed by a metal are bonded together by seam welding, as an example. In this case, the third layer 31c is soldered to a metallization layer (not illustrated) provided in a peripheral portion of the first layer 31a.

The internal space S which is sealed in an airtight manner in the package 30 is a decompressed vacuum state (state of a high degree of vacuum) or is filled with inert gas, such as, nitride, helium or argon. It is preferable that the internal space S is filled with the inert gas, such as, nitride, helium or argon rather than a vacuum state, in order to promote thermal conduction from the lid 32 to the quartz crystal resonator element 10.

A concave section 35 is provided in the second main surface 34 side of the package base 31 by the opening of the second layer 31b and the second mounting surface J2 of the first layer 31a. A plane shape of the concave section 35 is formed of, for example, a track shape.

Electrode pads J2a and J2b are provided at a position facing the electrodes 21 and 22 of the thermistor 20, in the second mounting surface J2 which is a bottom surface of the concave section 35.

The electrodes 21 and 22 of the thermistor 20 are bonded to the electrode pads J2a and J2b through a bonding member 41 such as a conductive adhesive or solder. As a result, the thermistor 20 is mounted on the second mounting surface J2 on the second main surface 34 side of the package base 31, and is contained in the concave section 35 (in other words, opening of the second layer 31b).

A length direction (direction in which the electrode 21 and the electrode 22 are coupled to each other) of the thermistor 20 coincides with a length direction (left-right direction of a sheet surface) of the package base 31, and the thermistor 20 is disposed in a substantially central portion of the concave section 35.

Electrode terminals 37a, 37b, 37c, and 37d are respectively provided in four corners of the second main surface 34 of the package base 31.

The two electrode terminals 37b and 37d located at, for example, one diagonal line within the four electrode terminals 37a to 37d are coupled to the internal terminals J1a and J1b connected to the lead-out electrodes 15a and 16a of the quartz crystal resonator element 10 through conductive vias (conductive electrodes which are obtained by filling through holes with a metal or a material with conductivity) V1 to V4 that respectively penetrate the first layer 31a and the second layer 31b of the package base 31 and internal wires P1 and P2.

The remaining two electrode terminals 37a and 37c located at the other diagonal line are coupled to electrode pads J2a and J2b connected to the electrodes 21 and 22 of the thermistor 20 through conductive vias V5 and V6 and internal wires P3 and P4.

The four electrode terminals 37a to 37d are formed of a shape in which a plane shape is a rectangular shape and a part of the concave section 35 side is notched.

If the lid 32 and the third layer 31c of the package base 31 are a metal, the electrode terminal 37c is electrically coupled to the lid 32 through the third layer 31c by either the conductive via V7 or a conductive film formed in a castellation (concave section, not illustrated) provided in a corner on the outside of the package base 31, and this is preferred from a viewpoint of improvement of shielding properties and promotion of thermal conduction. If the third layer 31c is insulating material, the conductive via is also provided in the third layer 31c.

In addition, the electrode terminal 37c of the quartz crystal resonator 1 is grounded as an earth terminal (GND terminal), and thereby shielding properties can be further improved.

The internal terminals J1a and J1b, the electrode pads J2a and J2b, and the electrode terminals 37a to 37d are formed of a metal-coated film in which a metallization layer such as W (tungsten) or Mo (molybdenum) is coated with each coated film such as Ni (nickel) or Au by plating or the like to be stacked.

As illustrated in FIG. 2, in the quartz crystal resonator 1, for example, in response to a drive signal which is applied to the quartz crystal resonator 1 from an oscillation circuit 61 that is integrated in an IC chip 70 of an electronic apparatus through the electrode terminals 37b and 37d, the quartz crystal resonator element 10 excites thickness shear vibration to resonate (oscillate) at a predetermined frequency, and thus a resonance signal (oscillation signal) is output from the electrode terminals 37b and 37d.

At this time, the thermistor 20 senses a temperature around the quartz crystal resonator element 10 as a temperature sensor, the quartz crystal resonator 1 converts the sensed temperature into a change of a voltage value which is supplied from a power supply 62, and outputs the change as a detection signal from the electrode terminal 37a.

For example, the detection signal which is output is converted into a digital signal by an A/D converting circuit 63 that is integrated in the IC chip 70 of the electronic apparatus, and is input to a temperature compensating circuit 64 which is integrated in the IC chip 70 of the electronic apparatus, in the same manner. Thus, the temperature compensating circuit 64 outputs a correction signal based on temperature compensation data to the oscillation circuit 61 in response to the detection signal which is input.

The oscillation circuit 61 applies the drive signal which is compensated on the basis of the correction signal that is input to the quartz crystal resonator element 10, and compensates for the resonance frequency of the quartz crystal resonator element 10 which varies depending on a temperature change so as to be a predetermined frequency. The oscillation circuit 61 amplifies an oscillation signal with the compensated frequency and outputs the oscillation signal to the outside.

At this time, the smaller a temperature difference between the temperature of the quartz crystal resonator element 10 and the temperature which is sensed by the thermistor 20 is (the more correct the detection signal is), the more accurately the quartz crystal resonator 1 can correct the resonance frequency of the quartz crystal resonator element 10.

As a result, the quartz crystal resonator 1 can obtain excellent frequency temperature characteristics, and can be accurate.

As described above, the quartz crystal resonator 1 according to the first embodiment includes the overlapping section (here, the first layer 31a) in which at least a portion of the first mounting surface J1 and at least a portion of the second mounting surface J2 overlap each other in which the quartz crystal resonator element 10 and the thermistor 20 of the package base 31 are mounted, and since the thickness t of the overlapping section (hereinafter, simply referred to as thickness t) is equal to or greater than 0.04 mm and less than 0.10 mm, thermal conduction between the quartz crystal resonator element 10 and the thermistor 20 through the package base 31 is promoted.

As a result, the quartz crystal resonator 1 can reduce a temperature difference between the temperature of the quartz crystal resonator element 10 and the temperature which is sensed by the thermistor 20, and can obtain excellent frequency temperature characteristics.

Accordingly, since a variation width of the frequency is small, the quartz crystal resonator 1 can be accurate.

Here, the above description will be made in detail.

As a method of achieving a thermal equilibrium state (state in which both have the same temperature) between the quartz crystal resonator element 10 and the thermistor 20 of the quartz crystal resonator 1 at the time of being mounted in a main circuit board (mother board) of a wireless communication apparatus such as a cellular phone which is an electronic apparatus in a shorter period of time, a thermal capacity of a conduction member such as the conduction vias V1 to V6 and the internal wires P1 to P4 can be approximately equal by a path from the electrode terminals 37b and 37d to the quartz crystal resonator element 10, and a path from the electrode terminals 37a and 37c to the thermistor 20, as described in JP-A-2013-102315.

The inventor sets the thickness t of the package base 31 to a value equal to or greater than 0.04 mm and less than 0.10 mm, based on an analysis result of simulation and experimentation which will be later, as a further improved method, and thereby while retaining a mechanical strength, a temperature difference between the temperature of the quartz crystal resonator element 10 and the temperature which is sensed by the thermistor 20 can be further reduced, and excellent frequency temperature characteristics can be obtained.

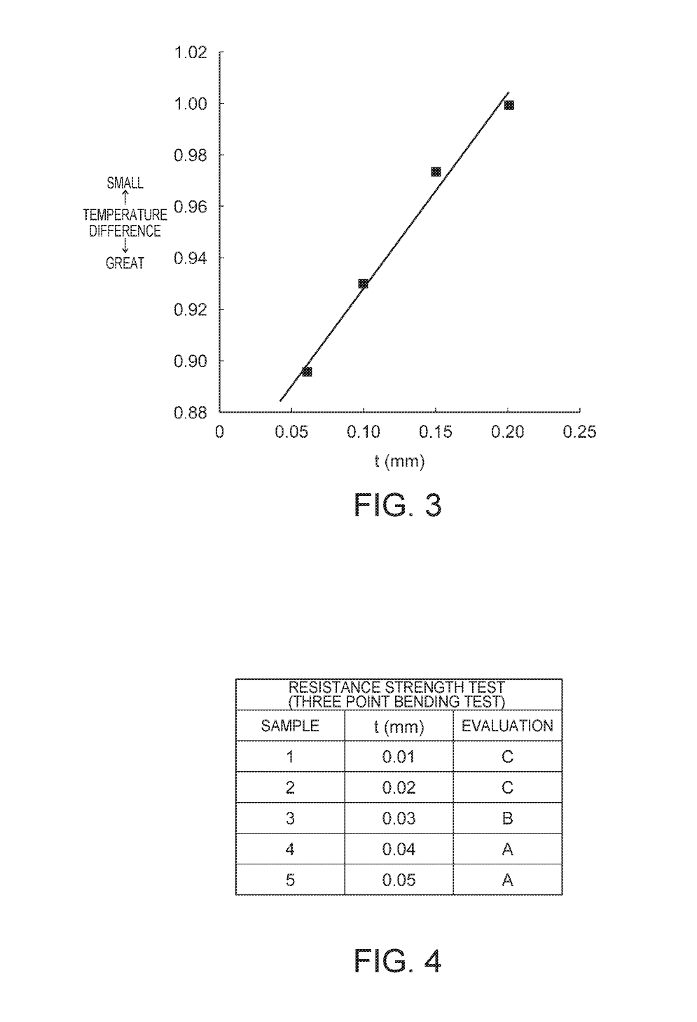

FIG. 3 is a graph illustrating a relationship between the thickness t of the package base and the temperature difference between the first mounting surface side and the second mounting surface side. The horizontal axis denotes the thickness t, and the vertical axis denotes of the value which comparatively figures a temperature difference between the first mounting surface side and the second mounting surface side such that the value is set to 1.00 when the thickness t is 0.20 mm. The vertical axis denotes that the greater the figures are, the greater the temperature difference is, and the smaller the figures are, the smaller the temperature difference is.

As illustrated in FIG. 3, it can be seen that, as the thickness t of the package base 31 becomes thinner, the temperature difference between the first mounting surface J1 side and the second mounting surface J2 side becomes smaller.

FIG. 4 is a diagram illustrating a relationship between the thickness t of the package base and a mechanical strength.

Here, a bending resistant strength test (three point bending test) was performed based on “JIS R 1601 method of testing room temperature bending strength of fine ceramics”. As a test result, a three-step evaluation of A (good), B (acceptable), and C (not acceptable) was conducted based on a magnitude of maximum bending stress when the package base 31 is broken.

As illustrated in FIG. 4, it can be seen that sample 1 (t=0.01 mm) and sample 2 (t=0.02 mm) marks C and do not withstand actual use. Sample 3 (t=0.03 mm) marks B, but in view of variation and margin at the time of mass production, it is considered that there is a large risk for actual use.

Meanwhile, it can be seen that sample 4 (t=0.04 mm) and sample 5 (t=0.05 mm) marks A and sufficiently withstand actual use.

As a result, the lower limit of the thickness t of the package base 31 for further reducing a temperature difference between the temperature of the quartz crystal resonator element 10 and the temperature which is sensed by the thermistor 20 while retaining mechanical strength is 0.04 mm.

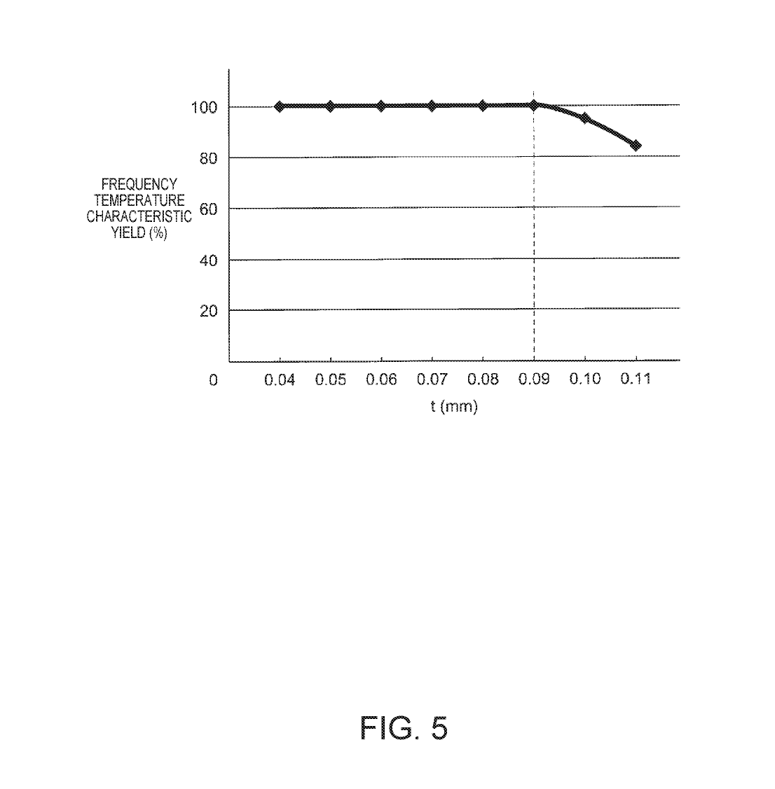

FIG. 5 is a graph illustrating a relationship between the thickness t of the package base and yield of the frequency temperature characteristics of the quartz crystal resonator. The horizontal axis denotes the thickness t, and the vertical axis denotes yield of the frequency temperature characteristics of the quartz crystal resonator.

As illustrated in FIG. 5, it can be seen that the yield of the frequency temperature characteristics deteriorate in accordance with an increase of the thickness t of the package base 31 up to 0.10 mm and 0.11 mm exceeding 0.09 mm.

This is because that, if the thickness t of the package base 31 increases up to 0.10 mm and 0.11 mm exceeding 0.09 mm, the temperature difference between the temperature of the quartz crystal resonator element 10 and the temperature which is sensed by the thermistor 20 increases, and thus correction of the resonance frequency of the quartz crystal resonator element 10 which is performed by the temperature compensating circuit 64 (refer to FIG. 2) becomes inaccurate.

As a result, the upper limit of the thickness t of the package base 31 for reducing the temperature difference between the temperature of the quartz crystal resonator element 10 and the temperature which is sensed by the thermistor 20 and obtaining better frequency temperature characteristics at a high yield is a value less than 0.10 mm.

In addition, in the quartz crystal resonator 1, if the thickness t of the package base 31 is equal to or greater than 0.04 mm and equal to or less than 0.08 mm, thermal conduction between the quartz crystal resonator element 10 and the thermistor 20 through the package base 31 will be further promoted.

In addition, in the quartz crystal resonator 1, if the thickness t of the package base 31 is equal to or greater than 0.04 mm and equal to or less than 0.06 mm, thermal conduction between the quartz crystal resonator element 10 and the thermistor 20 through the package base 31 will be further promoted.

In addition, the quartz crystal resonator 1 has a stacked structure in which the package base 31 has the first layer 31a with a thickness equal to or greater than 0.04 mm and less than 0.10 mm on the first main surface 33 side, and the second layer 31b with a thickness equal to or greater than that of the first layer 31a on the second main surface 34 side. The first mounting surface J1 and the second mounting surface J2 respectively are a front surface and a back surface of the first layer 31a, and the thermistor 20 is contained in the opening of the second layer 31b.

As a result, in the quartz crystal resonator 1, since the first layer 31a of the package base 31 is a flat plate shape, it is easy to manage the thickness t in a range equal to or greater than 0.04 mm and less than 0.10 mm. In addition, since the second layer 31b with a thickness equal to or greater than that of the first layer 31a is stacked on the first layer 31a, it is possible to ensure the strength of the package base 31.

In addition, since the thermistor 20 is contained in the opening (concave section 35) of the second layer 31b, whole quartz crystal resonator 1 can be thinned while ensuring the strength of the package base 31.

In addition, since the package base 31 is stacked on the first layer 31a and further includes the third layer 31c having a frame shape surrounding the quartz crystal resonator element 10, the quartz crystal resonator 1 is provided with the internal space S (concave section configuring the internal space S) which contains the quartz crystal resonator element 10 in the package base 31, and it is possible to further increase the strength of the package base 31.

In addition, the quartz crystal resonator 1 uses, for example, an aluminum nitride sintered body or a silicon carbide sintered body which contains aluminum nitride (thermal conductivity: approximately 150 W/(m·K) to 280 W/(m·K)) or silicon carbide (thermal conductivity: approximately 100 W/(m·K) to 350 W/(m·K)) which have relatively high thermal conductivity among ceramic-based insulating materials, as main components for the first layer 31a and the second layer 31b of the package base 31. In other words, at least the overlapping section of the package base 31 contains aluminum nitride or silicon carbide as main components.

As a result, in the quartz crystal resonator 1, since thermal conduction between the quartz crystal resonator element 10 and the thermistor 20 through the package base 31 is further promoted, it is possible to further reduce (close to a thermal equilibrium state) the temperature difference between the temperature of the quartz crystal resonator element 10 and the temperature which is sensed by the thermistor 20, and to obtain more excellent frequency temperature characteristics.

As a result, the quartz crystal resonator 1 can be more accurate.

In addition, in the quartz crystal resonator 1, since the electronic device is a temperature sensing device, it is possible to reduce the temperature difference between the temperature of the quartz crystal resonator element 10 and the temperature which is sensed by the temperature sensing device, and to obtain excellent frequency temperature characteristics.

In addition, since the temperature sensing device is the thermistor 20, the quartz crystal resonator 1 can correctly sense the surrounding temperature using the characteristics of the thermistor 20.

A semiconductor device for temperature measurement may be used as the temperature sensing device instead of the thermistor 20, and it is possible to correctly sense the surrounding temperature using characteristics of the semiconductor device for temperature measurement. A diode or a transistor can be used as the semiconductor device for temperature measurement.

In detail, in a case of a diode, using forward characteristics of the diode, the temperature can be sensed by flowing a constant current from an anode terminal to a cathode terminal of the diode and measuring, a forward voltage which changed depending on temperature. In addition, in a case of a transistor the temperature can be sensed in the same manner as described above by coupling a base to a collector to function as a diode.

As a diode or a transistor is used for a temperature sensing device, it is possible to suppress superposition of noise in the quartz crystal resonator 1.

In the quartz crystal resonator 1, if the package base 31 does not have a structure in which the first layer 31a, the second layer 31b, and the third layer 31c are stacked and instead, is formed of one piece, the overlapping section of the first mounting surface J1 and the second mounting surface J2 of the package base 31 is positioned in the inside of the concave section 35 in a planar view.

### Modification Example

Subsequently, a modification example of the first embodiment will be described.

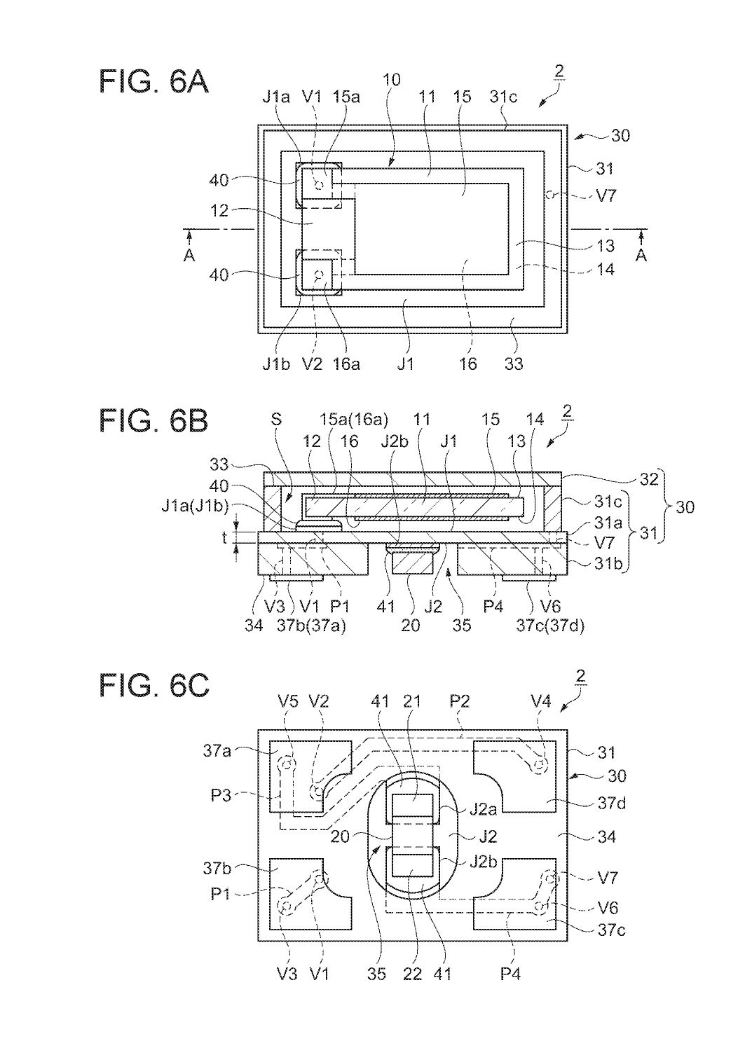

FIGS. 6A to 6C are schematic views illustrating a schematic configuration of a quartz crystal resonator according to a modification example of the first embodiment, FIG. 6A is a plan view viewed from a lid side, FIG. 6B is a sectional view taken along line A-A of FIG. 6A, and FIG. 6C is a plan view viewed from a bottom surface side.

The same symbols or reference numerals are attached to the same portions as those of the first embodiment, and description thereof will be omitted. Description will be focused on portions different from that of the first embodiment.

As illustrated in FIGS. 6A to 6C, a quartz crystal resonator 2 according to the modification example is different from that of the first embodiment in a disposition direction of the thermistor 20.

In the quartz crystal resonator 2, the thermistor is disposed in such a manner that a length direction (direction in which the electrode 21 is coupled to the electrode 22) of the thermistor 20 intersects with (here, orthogonal to) a length direction (left-right direction of a sheet surface) of the package base 31.

As a result, the quartz crystal resonator 2 can suppress a decrease of fixing strength (bonding strength) of the thermistor 20 associated with bending of the package base 31 which tends to bend large in a length direction, in addition to the effects of the first embodiment.

The configuration of the modification example can also be applied to the following embodiment.

### Second Embodiment

Subsequently, another configuration of a quartz crystal resonator serving as a resonator device will be described.

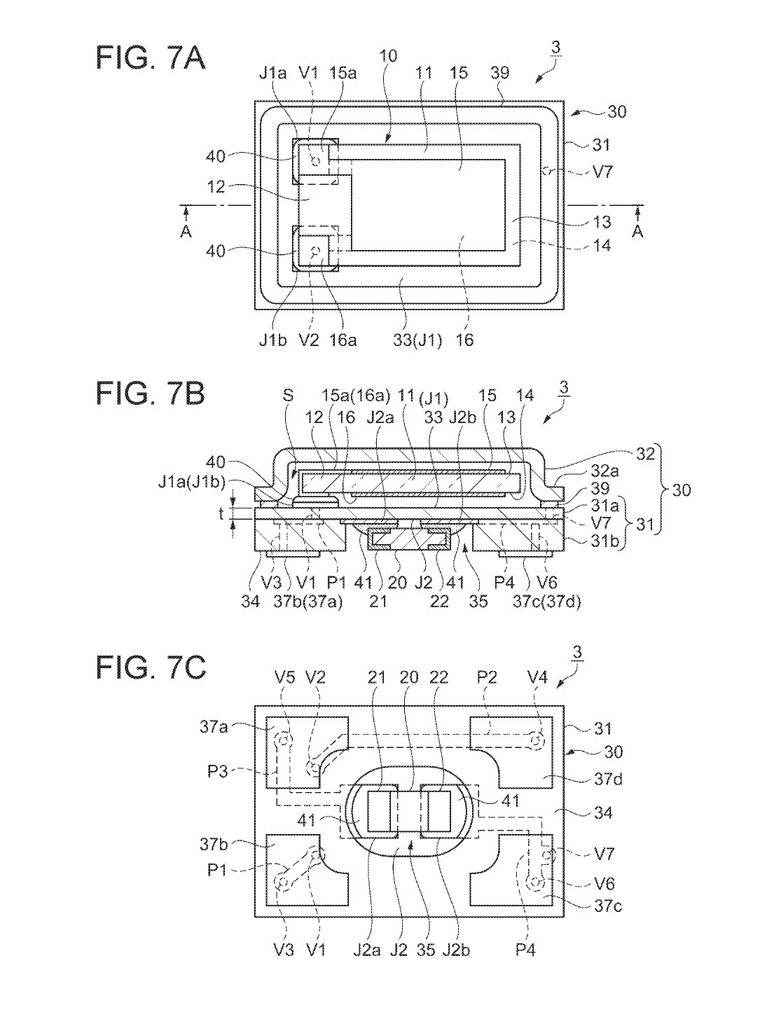

FIGS. 7A to 7C are schematic views illustrating a schematic configuration of a quartz crystal resonator according to a second embodiment, FIG. 7A is a plan view viewed from a lid side, FIG. 7B is a sectional view taken along line A-A of FIG. 7A, and FIG. 7C is a plan view viewed from a bottom surface side.

The same symbols or reference numerals are attached to the same portions as those of the first embodiment, and description thereof will be omitted. Description will be focused on portions different from that of the first embodiment.

As illustrated in FIGS. 7A to 7C, a quartz crystal resonator 3 according to the second embodiment is different from that of the first embodiment in configurations of the package base 31 and the lid 32.

In the quartz crystal resonator 3, the third layer 31c of the package base 31 is removed, and instead, a bonding member 39 between the package base 31 and the lid 32 is disposed. Accordingly, the quartz crystal resonator 3 has the package base 31 where the first main surface 33 and the first mounting surface J1 are the same surface.

The lid 32 is formed in a cap shape in which a flange section 32a is provided in the entire periphery, using a metal such as, Kovar or 42 alloy.

The quartz crystal resonator 3 ensures the internal space S which contains the quartz crystal resonator element 10 by bulge of a cap portion of the lid 32.

The flange section 32a of the lid 32 is coupled to the first main surface 33 (first mounting surface J1) of the package base 31 through the bonding member 39 with conductivity such as a seam ring, a brazing material, a conductive adhesive, or the like.

Accordingly, the lid 32 is electrically coupled to the electrode terminal 37c through the conductive vias V6 and V7, and the internal wire P4 in the package base 31 to obtain shield effects and to promote thermal conduction.

The lid 32 is electrically coupled to the electrode terminal 37c through the bonding member 39 and a conductive film formed in a castellation (not illustrated) provided on a corner of the outside of the package base 31.

As described above, since the third layer 31c of the package base 31 is removed from the quartz crystal resonator 3 according to the second embodiment, manufacture of the package base 31 is easier than that of the first embodiment.

In the quartz crystal resonator 3, the lid 32 may not be electrically coupled to the electrode terminal 37c, insofar as there is no hindrance to shield and the promotion of thermal conduction. As a result, the bonding member 39 may be a member having insulation properties.

### Electronic Apparatus

Subsequently, a cellular phone will be described as an example of an electronic apparatus including the resonator device described above.

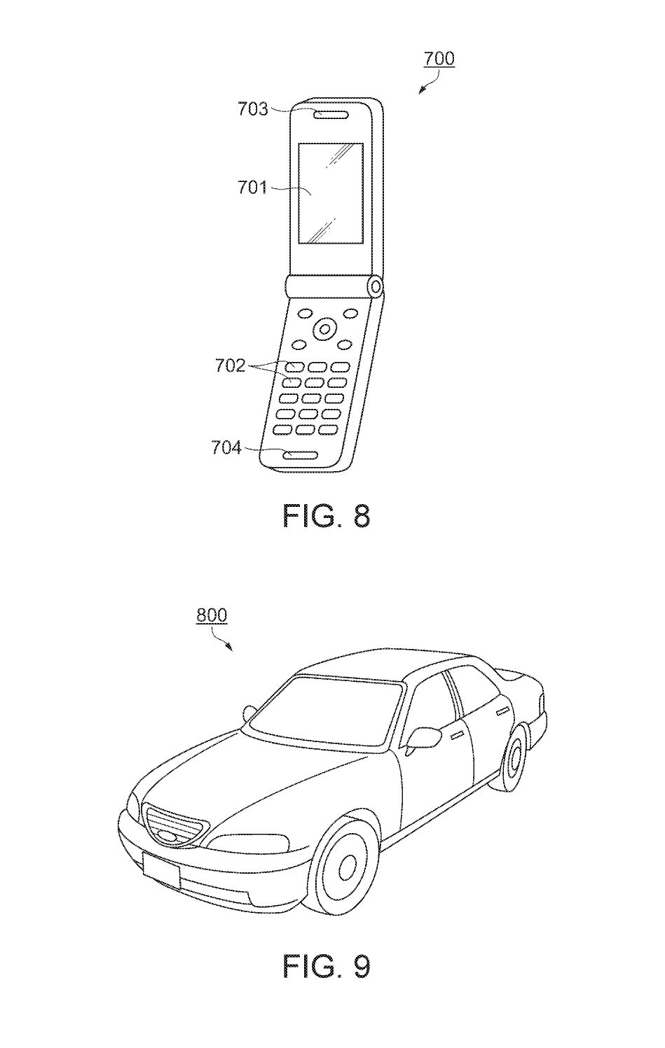

FIG. 8 is a schematic perspective view illustrating a cellular phone serving as an electronic apparatus.

A cellular phone 700 includes a quartz crystal resonator serving as the resonator device described in each embodiment and the modification example.

The cellular phone 700 illustrated in FIG. 8 uses the above-described quartz crystal resonator (any one of the quartz crystal resonators 1 to 3) as a timing device such as a reference clock generation source, and further includes a liquid crystal display device 701, a plurality of operation buttons 702, an ear piece 703, and a mouth piece 704. A shape of the cellular phone is not limited to the illustrated type, and may be a shape of a so-called smart phone type.

The resonator device such as the above-described quartz crystal resonator is not limited to a cellular phone, and can be appropriately used as a timing device of an electronic apparatus including an electronic book, a personal computer, a television, a digital still camera, a video camera, a video recorder, a navigation device, a pager, an electronic organizer, an electronic calculator, a word processor, a workstation, a television phone, a POS terminal, a game machine, a medical device (for example, an electronic thermometer, a blood pressure meter, a blood glucose meter, an electrocardiogram measuring device, an ultrasonic diagnostic apparatus, an electronic endoscope), a fish finder, various measurement equipment, instruments, a flight simulator, or the like. In any cases, it is possible to provide an electronic apparatus having the effects described in each embodiment and the modification example described above, and exerting excellent performance.

### Moving Object

Subsequently, an automobile will be described as an example of a moving object including the resonator device described above.

FIG. 9 is a schematic perspective view illustrating an automobile serving as a moving object.

An automobile 800 includes a quartz crystal resonator serving as the resonator device described in each embodiments and the modification example described above.

The automobile 800 uses the above-described quartz crystal resonator (any one of the quartz crystal resonators 1 to 3) as a timing device such as a reference clock generation source of each electronic control type device (for example, an electronic control type fuel injection device, an electronic control type ABS device, an electronic control type constant speed traveling device, or the like) which is mounted.

According to this, because of including the above-described quartz crystal resonator, the automobile 800 can obtain the effects described in each embodiment and the modification example described above, and exert excellent performance.

The resonator device such as the above-described quartz crystal resonator is not limited to the automobile 800, and can be appropriately used as a timing device such as a reference clock generation source of a moving object including a self-propelled robot, a self-propelled transport device, a train, a ship, an airplane, an artificial satellite, or the like. In any cases, it is possible to provide a moving object having the effects described in each embodiment and the modification example described above, and exerting excellent performance.

The shape of the resonator element of the quartz crystal resonator is not limited to a type of the illustrated flat plate shape, and may be a type (for example, convex type, bevel type, or mesa type) in which the central portion is thick and the peripheral portion is thin, a type (for example, reverse mesa type) in which the central portion is thin and the peripheral portion is thick, or a tuning fork shape.

A material of the resonator element is not limited to quartz crystal, and may be a piezoelectric body such as, lithium tantalate (LiTaO₃), lithium tetraborate (Li₂B₄O₇), lithium niobate (LiNbO₃), lead zirconate titanate (PZT), zinc oxide (ZnO), and aluminum nitride (AlN), or a semiconductor such as silicon (Si).

In addition, a driving method of thickness shear vibration may be electrostatic driving performed by coulomb's force in addition to piezoelectric effect of a piezoelectric body.

The entire disclosure of Japanese Patent Application No. 2015-000673, filed Jan. 6, 2015 is expressly incorporated by reference herein.

What is claimed is:

1. A resonator device comprising:
a resonator element;
an electronic device; and
a substrate including a first main surface and a second main surface which are respectively a front surface and a back surface,
wherein the resonator element is mounted on a first mounting surface on the first main surface side of the substrate,
wherein the electronic device is mounted on a second mounting surface on the second main surface side of the substrate,
wherein the substrate has an overlapping section in which at least a portion of the first mounting surface overlaps at least a portion of the second mounting surface in planar view, and
wherein a thickness of the overlapping section is equal to or greater than 0.04 mm and less than 0.10 mm.

2. The resonator device according to claim 1, wherein the thickness of the overlapping section is equal to or greater than 0.04 mm and equal to or less than 0.08 mm.

3. The resonator device according to claim 1, wherein the thickness of the overlapping section is equal to or greater than 0.04 mm and equal to or less than 0.06 mm.

4. The resonator device according to claim 1,
wherein the substrate has a stacked structure in which a first layer with a thickness equal to or greater than 0.04 mm and less than 0.10 mm is provided on the first main surface side and a second layer with a thickness equal to or greater than that of the first layer is provided on the second main surface side,
wherein the first mounting surface and the second mounting surface are respectively the front surface and the back surface of the first layer,
wherein the second layer has an opening larger than the electronic device in a planar view, and
wherein the electronic device is contained in the opening.

5. The resonator device according to claim 4, wherein the substrate is stacked on the first main surface side of the first layer, and further includes a third layer of frame shape surrounding the resonator element.

6. The resonator device according to claim 1, wherein at least the overlapping section of the substrate employs aluminum nitride or silicon carbide as main components.

7. The resonator device according to claim 1, wherein the electronic device is a temperature sensing device.

8. The resonator device according to claim 7, wherein the temperature sensing device is a thermistor or a semiconductor device for temperature measurement.

9. An electronic apparatus comprising:
the resonator device according to claim 1.

10. An electronic apparatus comprising:
resonator device according to claim 2.

11. An electronic apparatus comprising:
the resonator device according to claim 3.

12. An electronic apparatus comprising:
the resonator device according to claim 4.

13. An electronic apparatus comprising:
the resonator device according to claim 5.

14. An electronic apparatus comprising:
the resonator device according to claim 6.

15. A moving object comprising:
the resonator device according to claim 1.

16. A moving object comprising:
the resonator device according to claim 2.

17. A moving object comprising:
the resonator device according to claim 3.

18. A moving object comprising:
the resonator device according to claim 4.

19. A moving object comprising:
the resonator device according to claim 5.

20. A moving object comprising:
the resonator device according to claim 6.
